(19) United States
(12) Patent Application Publication
(10) Pub. No.: US 2017/0133573 A1
(43) Pub. Date: May 11, 2017

(54) THERMOELECTRIC DEVICE

(71) Applicant: Electronics and Telecommunications Research Institute, Daejeon (KR)

(72) Inventors: Seungeon MOON, Daejeon (KR); Junsoo KIM, Daejeon (KR); SEUNG MIN LEE, Suwon-si (KR)

(73) Assignee: Electronics and Telecommunications Research Institute, Daejeon (KR)

(21) Appl. No.: 15/346,101

(22) Filed: Nov. 8, 2016

(30) Foreign Application Priority Data
Nov. 10, 2015 (KR) 10-2015-0157629
Jul. 6, 2016 (KR) 10-2016-0085798

(51) Int. Cl. H01L 35/32; H01L 35/30

(52) U.S. Cl. CPC H01L 35/32; H01L 35/30

(57) ABSTRACT

Provided is a thermoelectric device. The thermoelectric device includes an upper substrate and a lower substrate, which face each other, and a thermoelectric conversion part disposed between the upper substrate and the lower substrate. The thermoelectric conversion part includes a first electrode disposed on the lower substrate, a second electrode spaced apart from the first electrode in a first direction on the lower substrate, a third electrode spaced apart from the first and second electrodes in a second direction perpendicular to the first direction on the lower substrate, a first thermoelectric member disposed between the first electrode and the third electrode and connected to the first electrode and the third electrode, and a second thermoelectric member disposed between the second electrode and the third electrode and connected to the second electrode and the third electrode. The lower substrate has a first lower opening that passes therethrough, and the first lower opening exposes the third electrode.

### CROSS-REFERENCE TO RELATED APPLICATIONS

This U.S. non-provisional patent application claims priority under 35 U.S.C. §119 of Korean Patent Application Nos. 10-2015-0157629, filed on Nov. 10, 2015, and 10-2016-0085798, filed on Jul. 6, 2016, the entire contents of which are hereby incorporated by reference.

### BACKGROUND

The present disclosure herein relates to a thermoelectric device.

A thermoelectric device converts thermal energy to electrical energy. The thermoelectric device has been interested due to a clean energy policy in recent years. The thermoelectric effect is discovered by Thomas Seebeck in the eighteen-hundreds. The Seebeck connects bismuth to copper with a compass disposed therebetween. When one side of the bismuth is heated, current is induced due to temperature difference. As the compass moves by magnetic field generated by the induced current, the thermoelectric effect is discovered.

A figure of merit (ZT) value is used as an index for thermoelectric efficiency.

ZT=S²*σ*T/κ (S: Seebeck coefficient, σ: Electrical conductivity, T: Absolute temperature, κ: Thermal conductivity)

The ZT value is proportional to a square of the Seebeck coefficient and the electrical conductivity. The ZT value is inversely proportional to the thermal conductivity. Metal has the low Seebeck coefficient and is proportional to the electrical conductivity and the thermal conductivity according to the Wiedemann Franz law. Accordingly, as improvement in the ZT value of the metal is limited, researches using absolute temperature difference have been progressed in recent years.

### SUMMARY

The present disclosure provides a thermoelectric device performing effective thermoelectric generation.

The object of the present disclosure is not limited to the aforesaid, but other objects not described herein will be clearly understood by those skilled in the art from descriptions below.

An embodiment of the inventive concept provides a thermoelectric device including: an upper substrate and a lower substrate, which face each other; and a thermoelectric conversion part disposed between the upper substrate and the lower substrate. The thermoelectric conversion part includes: a first electrode disposed on the lower substrate; a second electrode spaced apart from the first electrode in a first direction on the lower substrate; a third electrode spaced apart from the first and second electrodes in a second direction perpendicular to the first direction on the lower substrate; a first thermoelectric member disposed between the first electrode and the third electrode and connected to the first electrode and the third electrode; and a second thermoelectric member disposed between the second electrode and the third electrode and connected to the second electrode and the third electrode. The lower substrate has a first lower opening that passes therethrough, and the first lower opening exposes the third electrode.

In an embodiment, the lower substrate may include a first heat transfer material that fills the first lower opening, and the first heat transfer material may have a thermal conductivity less than that of the lower substrate.

In an embodiment, the thermoelectric device may further include: an insulation member disposed between the thermoelectric conversion part and the upper substrate; and a heat sink disposed between the insulation member and the upper substrate. The insulation member may have a through-hole that passes therethrough to expose the second electrode, and the heat sink may include a protruding portion inserted into the through-hole to contact the second electrode.

In an embodiment, the heat sink may have a thermal conductivity greater than that of the insulation member.

In an embodiment, the lower substrate may have a plurality of second lower openings disposed below the first and second electrodes, and the thermoelectric device may further include a plurality of heat supply members respectively disposed in the second lower openings to supply heat to the first and second electrodes.

In an embodiment, the heat supply members may be spaced apart from the first and second electrodes.

In an embodiment, the upper substrate may include: an upper opening that passes therethrough to expose the third electrode; and a second heat transfer material that fills the upper opening. The second heat transfer material may have a thermal conductivity greater than that of the upper substrate.

In an embodiment, each of the upper and lower substrates may include poly-dimethyllesiloxane (PDMS) or polyurethane.

In an embodiment, the first thermoelectric member may include a first conductive semiconductor, and the second thermoelectric member may include a second conductive semiconductor that is different from the first conductive semiconductor.

In an embodiment, the first conductive semiconductor may be one of a P-type semiconductor and an N-type semiconductor, and the second conductive semiconductor may be the other of the P-type semiconductor and the N-type semiconductor.

In an embodiment, wherein the first direction and the second direction may be parallel to a top surface of the lower substrate.

In an embodiment, each of the thermoelectric conversion part and the first lower opening may be provided in plurality.

In an embodiment of the inventive concept, a thermoelectric device includes: an upper substrate and a lower substrate, which face each other; a thermoelectric conversion part disposed between the upper substrate and the lower substrate; an insulation member disposed between the thermoelectric conversion part and the upper substrate; and a heat sink disposed between the insulation member and the upper substrate. The thermoelectric conversion part includes: a first electrode disposed on the lower substrate; a second electrode spaced apart from the first electrode in a first direction on the lower substrate; a third electrode spaced apart from the first and second electrodes in a second direction perpendicular to the first direction on the lower substrate; a first thermoelectric member disposed between the first electrode and the third electrode to contact the first electrode and the third electrode; and a second thermoelectric member disposed between the second electrode and the third electrode to contact the second electrode and the third electrode. The insulation member has a through-hole that passes therethrough to expose the third electrode, and the heat sink includes a protruding portion inserted into the through-hole to contact the third electrode.

Particularities of other embodiments are included in the detailed description and drawings.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a view for explaining a thermoelectric generation apparatus using a thermoelectric device according to embodiments of the inventive concept;

FIG. 2 is a view of the thermoelectric generation apparatus in FIG. 1;

FIG. 3 is a plan view for explaining a lower substrate and a thermoelectric conversion part of the thermoelectric device in FIG. 2;

FIG. 4 is a plan view for explaining a lower substrate of the thermoelectric device in FIG. 2;

FIG. 5 is a cross-sectional view taken along line I-I′ of FIG. 2;

FIG. 6 is a cross-sectional view taken along line II-II′ of FIG. 2;

FIG. 7 is a view illustrating a thermoelectric generation apparatus according to embodiments of the inventive concept;

FIG. 8 is a cross-sectional view taken along line I-I′ of FIG. 7;

FIG. 9 is a cross-sectional view taken along line II-II′ of FIG. 7;

FIG. 10 is a view illustrating a thermoelectric generation apparatus according to embodiments of the inventive concept; and

FIG. 11 is a cross-sectional view taken along line I-I′ of FIG. 11.

### DETAILED DESCRIPTION

Advantages and features of the present disclosure, and implementation methods thereof will be clarified through following embodiments described with reference to the accompanying drawings. The present invention may, however, be embodied in many different forms and should not be construed as being limited to the embodiments set forth herein. Rather, these embodiments are provided so that this disclosure will be thorough and complete, and will fully convey the concept of the invention to those skilled in the art. Further, the present invention is only defined by scopes of claims. Like reference numerals refer to like elements throughout.

In the following description, the technical terms are used only for explaining a specific exemplary embodiment while not limiting the present disclosure. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

The object of the present invention is not limited to the aforesaid, but other objects not described herein will be clearly understood by those skilled in the art from descriptions below. Terms as defined in a commonly used dictionary should be construed as having the same meaning as in an associated technical context, and unless defined apparently in the description, the terms are not ideally or excessively construed as having formal meaning.

Hereinafter, the present disclosure will be described with reference to the accompanying drawings for explaining a thermoelectric device according to embodiments of the inventive concept.

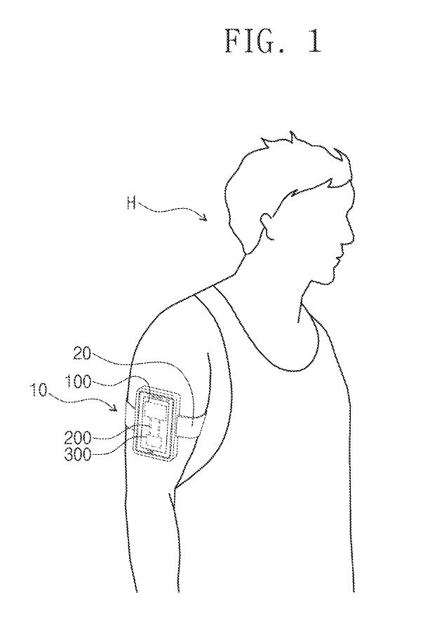

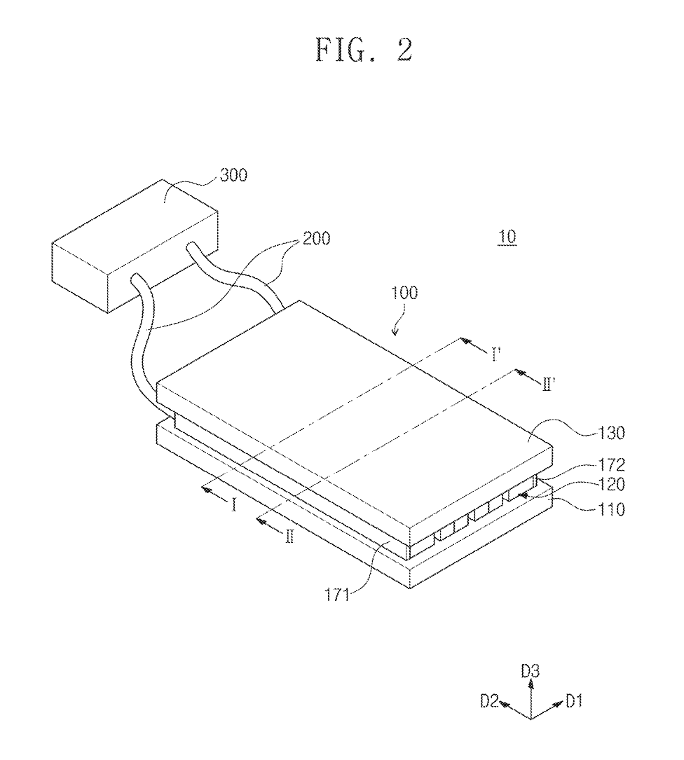

FIG. 1 is a view for explaining a thermoelectric generation apparatus using the thermoelectric device according to embodiments of the inventive concept. FIG. 2 is a view of the thermoelectric generation apparatus in FIG. 1.

Referring to FIGS. 1 and 2, a thermoelectric generation apparatus 10 using a thermoelectric device 100 according to embodiments of the inventive concept may be provided. The thermoelectric generation apparatus 10 may be configured to be wearable on a human body H by using a coupling member 20. Alternatively, according to another embodiment, the thermoelectric generation apparatus 10 may be installed on a heater such as electronic equipment.

The thermoelectric generation apparatus 10 may include the thermoelectric device 100, conductive lines 200, and an electronic unit 300. The thermoelectric generation apparatus 10 may convert thermal energy of the human body H to electrical energy and provide the converted electrical energy to the electronic unit 300. According to embodiments of the inventive concept, the electronic unit 300 may be a storage battery. However, an embodiment of the inventive concept is not limited to the kind of the electronic unit 300.

The thermoelectric device 100 may perform a function converting thermal energy to electrical energy by using the Seebeck effect in which electromotive force is generated by temperature difference. The thermoelectric device 100 may include a lower substrate 110 and an upper substrate 130, which face each other. The thermoelectric device 100 may include a pair of connecting electrodes 171 and 172 disposed between the lower substrate 100 and the upper substrate 130. The thermoelectric device 100 may include a thermoelectric conversion part 120 disposed between the lower substrate 100 and the upper substrate 130. The thermoelectric conversion part 120 may be disposed between the connecting electrodes 171 and 172.

The thermoelectric device 100 according to embodiments of the inventive concept may be configured to contact a skin of the human body H. The human body H may have a temperature of about 36.5° C., and an atmospheric temperature may be about 25° C. that is lower than that of the human body. The thermoelectric device 100 may have a temperature less than that of the human body H and greater than that of the atmosphere. Hereinafter, the human body H is referred to as a high temperature region, and the atmosphere is referred to as a low temperature region.

According to embodiments of the inventive concept, the lower substrate 110 may contact the high temperature region, and the upper substrate 130 may contact the low temperature region. Alternatively, according to other embodiments of the inventive concept, the lower substrate 110 may contact the low temperature region, and the upper substrate 130 may contact the upper temperature region. Hereinafter, unless otherwise specifically defined herein, the lower substrate 110 contacts the high temperature region, and the upper substrate 130 contacts the low temperature region.

In general, thermal energy moves from high temperature to low temperature for thermal equilibrium. According to embodiments of the inventive concept, the lower substrate 110 may receive the thermal energy from the high temperature region, and the upper substrate 130 may discharge the thermal energy to the low temperature region. That is, the lower substrate 110 may increase in temperature, and the upper substrate 130 may decrease in temperature. Accordingly, temperature difference may be generated between the lower substrate 110 and the upper substrate 130.

The thermoelectric device 100 may generate electrical energy by using the temperature difference between the upper substrate 130 and the lower substrate 110. A process in which the thermoelectric device 100 generates the electrical energy will be described later.

The electrical energy generated from the thermoelectric device 100 may be provided to the electronic unit 300 through conductive lines 200. According to embodiments of the inventive concept, the electrical energy may be stored in the storage battery.

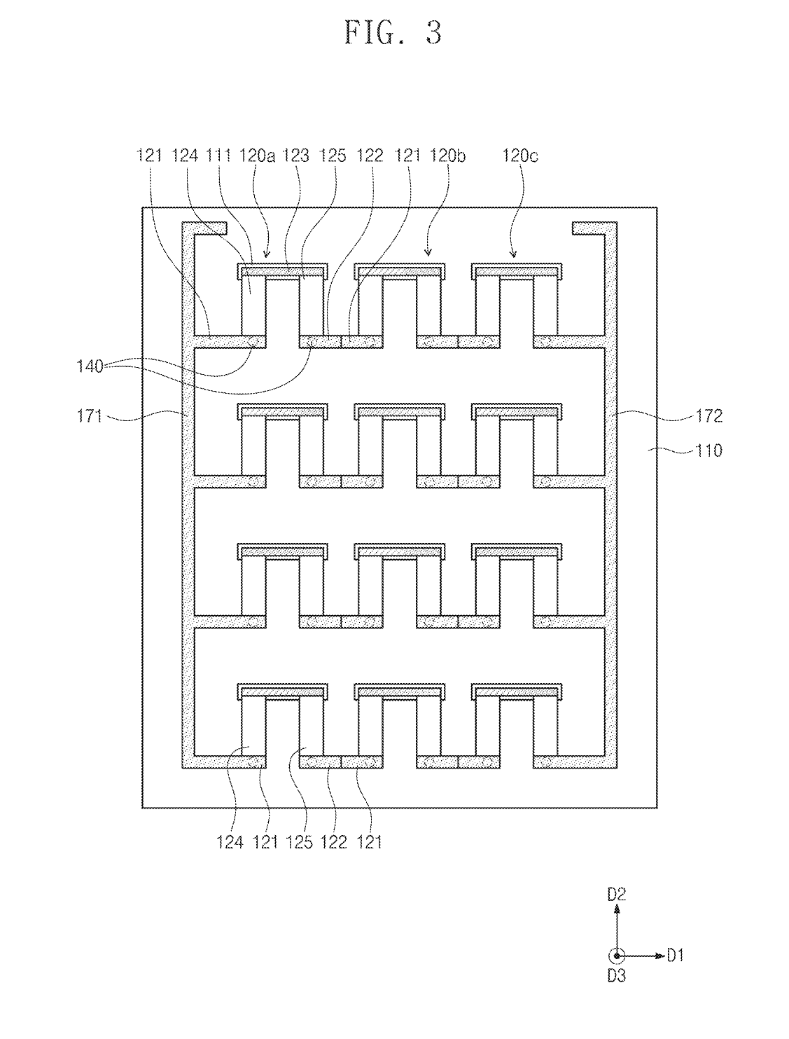

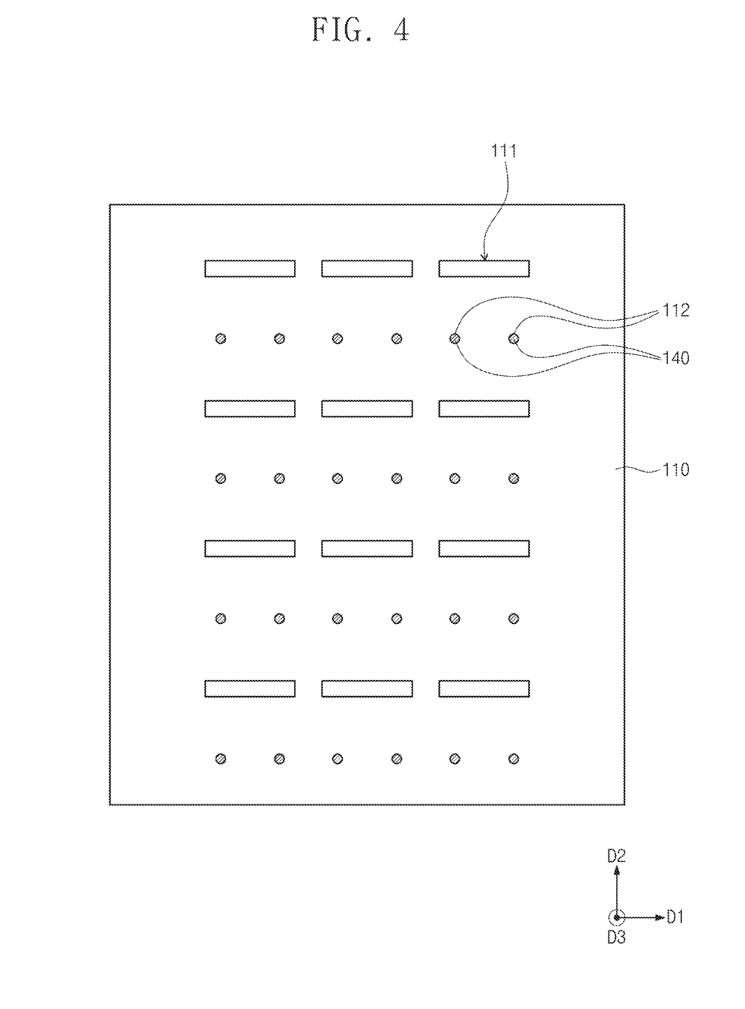

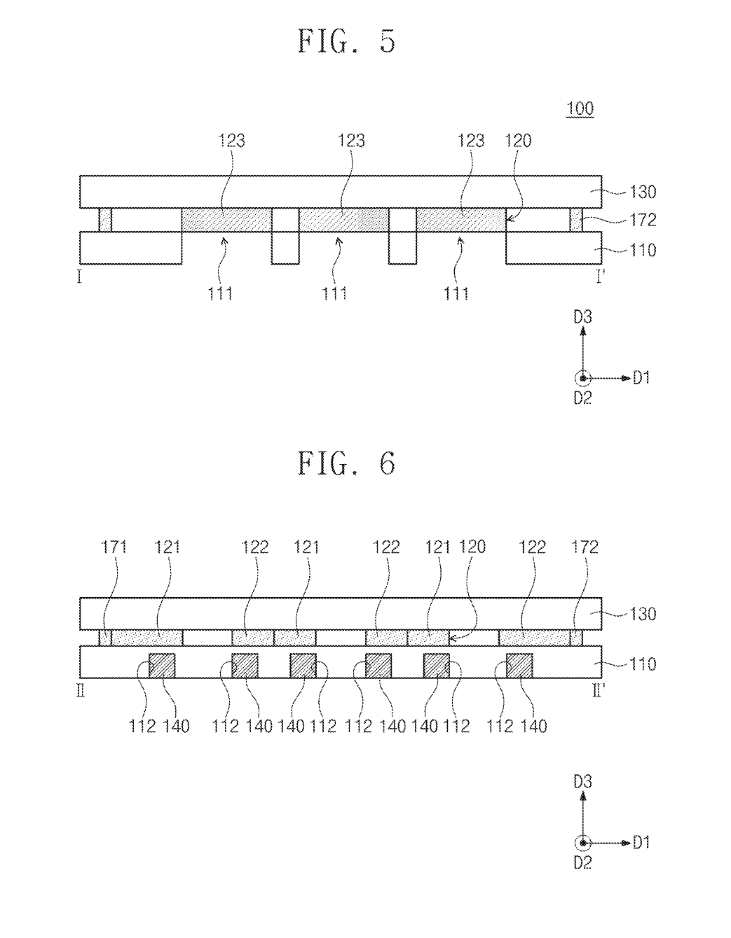

FIG. 3 is a plan view for explaining the lower substrate and the thermoelectric conversion part of the thermoelectric device. FIG. 4 is a plan view for explaining the lower substrate of the thermoelectric device. FIG. 5 is a cross-sectional view taken along line I-I′ of FIG. 2. FIG. 6 is a cross-sectional view taken along line II-II′ of FIG. 2.

Referring to FIGS. 2 to 6, the thermoelectric device 100 may include the lower substrate 110, thermoelectric conversion parts 120a to 120c, the connecting electrodes 171 and 172, the upper substrate 130, and heat supply members 140.

A plurality of thermoelectric conversion parts 120 may be disposed on the lower substrate 110. Each of the thermoelectric conversion parts 120 may include a first electrode 121, a second electrode 122, a third electrode 123, a first thermoelectric member 124, and a second thermoelectric member 125.

According to embodiments of the inventive concept, although twelve thermoelectric conversion parts 120 are provided, an embodiment of the inventive concept is not limited thereto. The first to third thermoelectric conversion parts 120a to 120c may be arranged in a first direction D1 parallel to a top surface of the lower substrate 110. The first to third thermoelectric conversion parts 120a to 120c arranged in the first direction D1 may be electrically connected to each other. The first to third thermoelectric conversion parts 120a to 120c arranged in the first direction D1 may be referred to as a first thermoelectric conversion set. The first thermoelectric conversion set may be arranged in a second direction D2. The thermoelectric conversion parts 120 may be arranged in a matrix structure between the lower substrate 110 and the upper substrate 130. In a typical thermoelectric device, the first electrode 121, the first thermoelectric member 124, and the third electrode 123 may be arranged vertically to the top surface of the lower substrate 110. The second electrode 122, the second thermoelectric member 124, and the third electrode 123 may be arranged vertically to the top surface of the lower substrate 110. Thus, the typical thermoelectric device may have a vertical structure. However, as illustrated in FIG. 3, in the thermoelectric device 100 according to an embodiment of the inventive concept, the first electrode 121, the first thermoelectric member 124, and the third electrode 123 may be arranged parallel to the top surface of the lower substrate 110 in the second direction D2. In the thermoelectric device 100, the second electrode 122, the second thermoelectric member 124, and the third electrode 123 may be arranged parallel to the top surface of the lower substrate 110 in the second direction D2. Accordingly, the thermoelectric device 100 according to embodiments of the inventive concept may have a horizontal structure.

The horizontal structured thermoelectric device 100 may have a thickness less than that of the typical thermoelectric device having the vertical structure. Here, the thickness may represent a length of the thermoelectric device 100 in a third direction D3.

The first electrode 121 may be disposed on the lower substrate 110. The first electrode 121 may be connected to the first thermoelectric member 124. The second electrode 122 may be disposed on the lower substrate 110. The second electrode 122 may be connected to the second thermoelectric member 125.

The second electrode 122 may be spaced apart from the first electrode 122 in the first direction D1. The second electrode 122 of the first thermoelectric conversion part 120a may be connected to the first electrode 121 of the second thermoelectric conversion part 120b disposed adjacently in the first direction D1. According to embodiments of the inventive concept, the second electrode 122 of the first thermoelectric conversion part 120a and the first electrode 121 of the second thermoelectric conversion part 120b disposed adjacently in the first direction D1 may be provided as a single conductor.

The third electrode 123 may be disposed on the lower substrate 110. The third electrode 123 may be spaced apart from the first electrode 121 and the second electrode 122 in the second direction D2 perpendicular to the first direction D1. The third electrode 123 may be connected in common to the first and second thermoelectric members 124 and 125.

The connecting electrodes 171 and 172 may be connected to conductive lines 200 (refer to FIG. 2). Also, one of the connecting electrodes 171 and 172 may be electrically connected to at least one first electrode 121. The other of the connecting electrodes 171 and 172 may be electrically connected to at least one second electrode 122. According to embodiments of the inventive concept, the first electrode 121 of the first thermoelectric conversion part 120a and the second electrode 122 of the third thermoelectric conversion part 120c may be connected to the connecting electrodes 171 and 172, respectively.

The first to third electrodes 121 to 123 and the connecting electrodes 171 and 172 may be conductors. The first to third electrodes 121 to 123 and the connecting electrodes 171 and 172 may include metal, a conductive metal nitride, or a doped semiconductor material. For example, the first to third electrodes 121 to 123 and the connecting electrodes 171 and 172 may include at least one of aluminum (Al), copper (Cu), tungsten (W), titanium (Ti), silver (Ag), gold (Au), platinum (Pt), nickel (Ni), carbon (C), molybdenum (Mo), tantalum (Ta), iridium (Ir), ruthenium (Ru), zinc (Zn), tin (Sn), gallium (Ga), and indium (In).

Referring to FIG. 3, the first and second thermoelectric members 124 and 125 may be disposed on the lower substrate 110. The first and second thermoelectric members 124 and 125 are lengthily provided in the second direction D2. The first and second thermoelectric members 124 and 125 may be disposed parallel to the top surface of the lower substrate 110.

The first thermoelectric member 124 may be disposed between the first electrode 121 and the third electrode 123 and connected to the first electrode 121 and the third electrode 123. For example, the first thermoelectric member 124 may have one end connected to the first electrode 121 and the other end connected to the third electrode 123. Accordingly, the first thermoelectric member 124 may receive the thermal energy from the first and third electrodes 121 and 123.

The second thermoelectric member 125 may be disposed between the second electrode 122 and the third electrode 123 and connected to the second electrode 122 and the third electrode 123. For example, the second thermoelectric member may have one end connected to the second electrode 122 and the other end connected to the third electrode 123. Accordingly, the second thermoelectric member 125 may receive the thermal energy from the second and third electrodes 122 and 123.

The second thermoelectric member 125 may be spaced apart from the first thermoelectric member 124 in the first direction D1. That is, the first and second thermoelectric members 124 and 125 may be physically separated. The first and second thermoelectric members 124 and 125 may be semiconductors including silicon (Si) or germanium (Ge). The first thermoelectric member 124 may include a first conductive semiconductor. The second thermoelectric member 125 may include a second conductive semiconductor that is different from the first conductive semiconductor. The first conductive semiconductor may be one of a P-type semiconductor and an N-type semiconductor, and the second conductive semiconductor may be the other of the P-type semiconductor and the N-type semiconductor. According to embodiments of the inventive concept, the first thermoelectric member 124 may include a P-type semiconductor, and the second thermoelectric member 125 may include an N-type semiconductor.

The lower substrate 110 may include a semiconductor substrate, an insulated semiconductor substrate, or an insulated substrate. The lower substrate 110 may have at least one first lower opening 111 passing therethrough. The first lower opening 111 may be disposed to correspond to the third electrode 123. Accordingly, the first lower opening 111 may expose a lower portion of the third electrode 123. That is, the first lower opening 111 may be a hole. The first lower opening 111 may extend from a bottom surface 110b of the lower substrate 110 toward the third electrode 123. Although the first lower opening 111 may be defined vertically from the bottom surface 110b of the lower substrate 110, an embodiment of the inventive concept is not limited thereto. For example, the first lower opening 111 may be inclined from the bottom surface 110b of the lower substrate 110.

According to embodiments of the inventive concept, the first lower opening 111 may be filled with air on the inside of the first lower opening 111. The air may have a thermal conductivity less than that of the lower substrate 110. According to other embodiments, the first opening 111 may be filled with a first heat transfer material on the inside of the first opening 111. As illustrated in FIG. 4, the first lower openings 111 may be arranged in the first and second directions D1 and D2. That is, the first lower openings 111 may be arranged in the matrix structure.

The lower substrate 110 may have a plurality of second lower openings 112 into which the heat supply members 140 are respectively inserted. The second lower openings 122 may be disposed below the first and second electrodes 121 and 122. According to embodiments of the inventive concept, the second lower openings 122 may be grooves that do not expose the first and second electrodes 121 and 122. Alternatively, according to other embodiments of the inventive concept, the second lower openings 122 may be holes that expose the first and second electrodes 121 and 122.

The lower substrate 110 may include a flexible material. For example, the lower substrate 110 may include poly-dimethyllesiloxane (PDMS) or polyurethane. The poly-dimethyllesiloxane (PDMS) or polyurethane may have the thermal conductivity greater than that of the air. Accordingly, the lower substrate 110 may have the thermal conductivity greater than that of the air and be easily bent. An adhesion agent (not shown) may be applied to a lower portion of the lower substrate 110.

The upper substrate 130 may be disposed on the thermoelectric conversion parts 120. That is, the upper substrate 130 may cover the thermoelectric conversion parts 120. The upper substrate 130 may include a semiconductor substrate, an insulated semiconductor substrate, or an insulated substrate. The upper substrate 130 may include a flexible material. For example, the upper substrate 130 may include poly-dimethyllesiloxane (PDMS) or polyurethane. Accordingly, the upper substrate 130 may have the thermal conductivity greater than that of the air and be easily bent.

The heat supply members 140 may be disposed in the second lower openings 112 to supply heat to each of the first and second electrodes 121 and 122. Here, the heat may represent the thermal energy. Although the heat supply members 140 may include a plurality of heat pipes through which high temperature water or air flows, an embodiment of the inventive concept is not limited thereto.

As described above, each of the second lower openings 112 may be provided as a groove. Accordingly, the heat supply members 140 may be spaced apart from the first and second electrodes 121 and 122. As the heat supply members 140 are spaced apart from the first and second electrodes 121 and 122, the first and second electrodes 121 and 122 may be prevented from being damaged by the heat supply members 140.

According to embodiments of the inventive concept, operation of the thermoelectric device 100 configured as described above will be described with reference to FIGS. 1 to 6.

The lower substrate 110 may be disposed on the high temperature region. The upper substrate 130 may be disposed on the low temperature region. Accordingly, the thermal energy in the high temperature region may be transferred to the lower substrate 110. The first and second electrodes 121 and 122 that are directly connected to the lower substrate 110 may receive the thermal energy in the high temperature region through the lower substrate 110. However, the third electrode 123 may receive the thermal energy in the high temperature region through the air in the first lower opening 111. As described above, since the air has the thermal conductivity less than that of the lower substrate 110, the third electrode 123 may receive the thermal energy in the high temperature region less than that of each of the first and second electrodes 121 and 122. Accordingly, each of the first and second electrodes 121 and 122 may have a temperature greater than that of the third electrode 123. That is, temperature difference may be generated between the first and third electrodes 121 and 123, and temperature difference may be also generated between the second and third electrodes 123 and 123. Due to the temperature difference between the first electrodes 121 and third electrodes 123, and the temperature difference between the second electrodes 122 and third electrodes 123, the thermoelectric conversion parts 120 may generate the electrical energy.

According to embodiments of the inventive concept, the first thermoelectric member 124 may include the P-type semiconductor, and the second thermoelectric member 125 may include the N-type semiconductor. Electrons of the second thermoelectric member 125 may be excited by the thermal energy transferred from the second electrode 122 to move toward the third electrode 123. Electrons of the second thermoelectric member 125 may be excited by the thermal energy transferred from the third electrode 123 to move toward the second electrode 122. However, as the second electrode 122 transfers the thermal energy greater than that of the third electrode 123, to the second thermoelectric member 125, the electrons moving to the third electrode 123 are greater in number than those moving to the second electrode 122. Accordingly, the thermoelectric conversion part 120 may generate current flowing from the first electrode 121 to the second electrode 122 through the third electrode 123. That is, the thermoelectric conversion part 120 may generate the electrical energy. Also, as the temperature difference increases, the electrical energy generated by the thermoelectric conversion part 120 may increase in amount. Thus, it is important that the thermoelectric device 100 maintains the temperature difference.

The heat supply members 140 may supply heat to the first and second electrodes 121 and 122. Accordingly, the temperature difference between the first and third electrodes 121 and 123 may further increase. The temperature difference between the second and third electrodes 122 and 123 may further increase. That is, the electrical energy generated by the thermoelectric conversion part 120 may increase in amount.

Alternatively, the lower substrate 110 may be disposed in the lower temperature region, and the upper substrate 130 may be disposed in the high temperature region. Here, the heat supply members 140 may stop supplying the heat to the first and second electrodes 121 and 122. The first to third electrodes 121 to 123 may receive the thermal energy in the high temperature region through the upper substrate 130. Here, the first to third electrodes 121 to 123 may receive approximately the same amount of the thermal energy.

The first and second electrodes 121 and 122 may transfer the thermal energy to the low temperature region through the lower substrate 110. According to embodiments of the inventive concept, the third electrode 123 may transfer the thermal energy to the low temperature region through the air in the first lower opening 111. However, since the air has the thermal conductivity less than that of the lower substrate 110, the third electrode 123 may transfer the thermal energy less than that of the first and second electrodes 121 and 122 to the low temperature region. Accordingly, the first and second electrodes 121 and 122 may be less in temperature than the third electrode 123. That is, the temperature difference may be generated between the first and third electrodes 121 and 123, and temperature difference may be also generated between the second and third electrodes 123 and 123. As the above-described temperature difference is generated, the thermoelectric conversion part 120 may generate the electrical energy.

For example, the first thermoelectric member 124 may include the P-type semiconductor, and the second thermoelectric member 125 may include the N-type semiconductor. Electrons of the second thermoelectric member 125 may be excited by receiving the thermal energy from the third electrode 123. The excited electrons may move to the second electrode 122. Accordingly, current may flow in a direction opposite to the first direction D1 in the thermoelectric conversion part 120. That is, the thermoelectric conversion part 120 may generate the electrical energy.

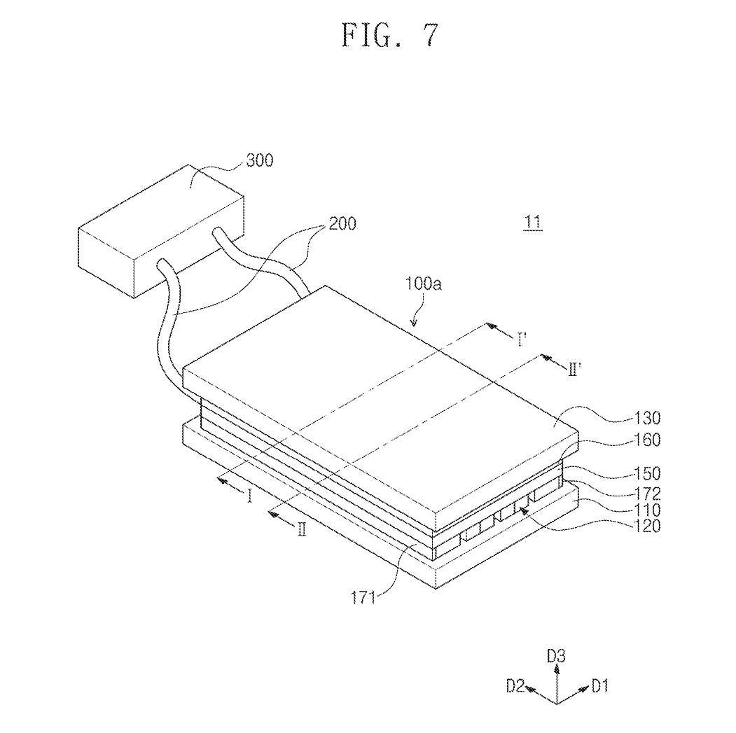

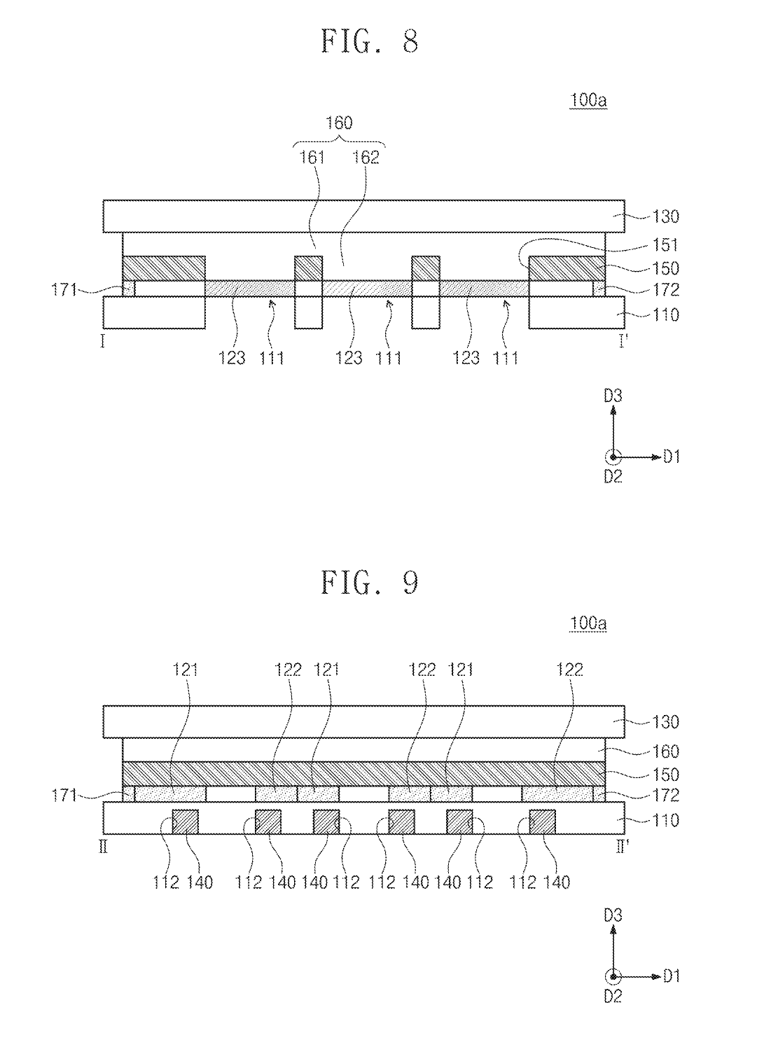

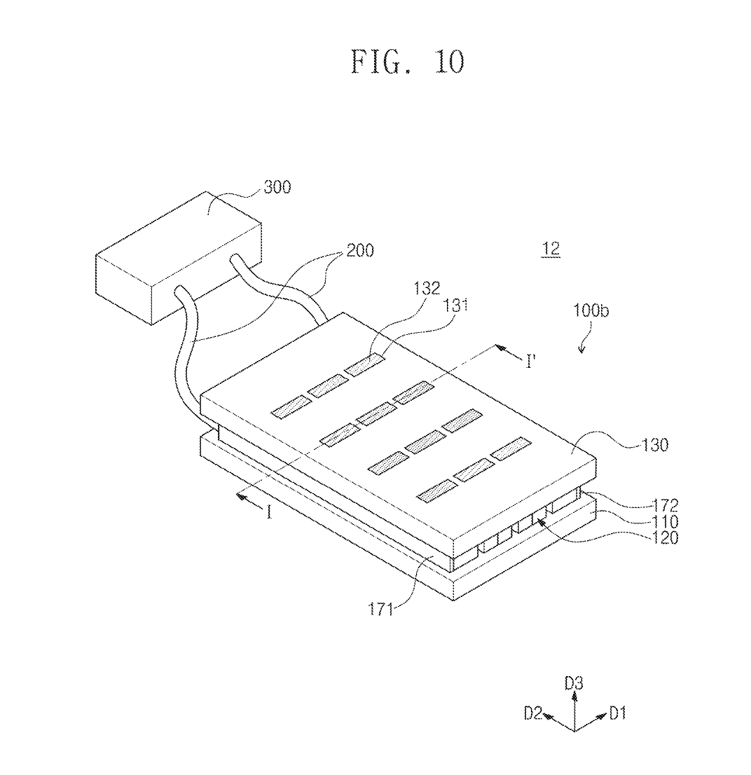

FIG. 7 is a view illustrating a thermoelectric generation apparatus according to an embodiment of the inventive concept FIG. 8 is a cross-sectional view taken along line I-I′ of FIG. 7. FIG. 9 is a cross-sectional view taken along line II-II′ of FIG. 7. For simplicity in description, description for components that are substantially the same as those of embodiments described with reference to FIGS. 2 and 6 will be omitted or simply described.

Referring to FIGS. 7 and 9, a thermoelectric device 100a according to embodiments of the inventive concept may include a lower substrate 110, a thermoelectric conversion part 120, and an upper substrate 130. The thermoelectric device 100 may further include a heat supply member 140, an insulation member 150, and a heat sink 160. According to embodiments of the inventive concept, the lower substrate 110 may have a first lower opening 111. Alternatively, according to another embodiment of the inventive concept, the lower substrate 110 may not have the first lower opening 111. Also, the lower substrate 110 may have a plurality of second lower openings 112.

An insulation member 150 may be disposed on the thermoelectric conversion part 120. The insulation member 150 may be disposed between the upper substrate 130 and the thermoelectric conversion part 120. The insulation member 150 may block the thermal energy moving between the thermoelectric conversion part 120 and the upper substrate 130. The insulation member 150 may include a material having a low thermal conductivity. For example, the insulation member 150 may include at least one of cork, felt, carbonized cork, rubber, asbestos, glass wool, quartz wool, diatomite, magnesium carbonate, magnesia, calcium silicate, perlite, and sodium silicate.

The insulation member 150 may have a through-hole 151 at a position corresponding to the third electrode 123. That is, the insulation member 150 may be disposed on the third electrode 123. Accordingly, the through-hole 151 may expose an upper portion of the third electrode 123.

The heat sink 160 may be disposed on the insulation member 150. The heat sink 160 may be disposed between the insulation member 150 and the upper substrate 130. The heat sink 160 may have the thermal conductivity that is much greater than that of the insulation member 150. Also, the heat sink 160 may have the thermal conductivity greater than that of the upper substrate 130. The heat sink 160 may include a material having the excellent thermal conductivity. For example the heat sink 160 may include a metal material such as gold (Au), silver (Ag), and copper (Cu). The heat sink 160 may include a base portion 161 and at least one protruding portion 162.

The base portion 161 may correspond to a shape of the upper substrate 130. For example, although each of the upper substrate 130 and the base portion 161 may have a rectangular shape, an embodiment of the inventive concept is not limited thereto. A top surface of the base portion 161 may contact a bottom surface of the upper substrate 130. Also, as a contact area between the base portion 161 and the upper substrate 130 increases, a heat transfer efficiency to the upper substrate 130 may increase.

The protruding portion 162 may protrude from a bottom surface of the base portion 161 to the upper portion of the third electrode 123. The protruding portion 162 may be inserted into the through-hole 151 to directly contact the upper portion of the third electrode 123. As illustrated in FIG. 8, the heat sink 160 may include three protruding portions 162.

When the upper substrate 130 is disposed in the low temperature region, the upper substrate 130 may have a temperature less than that of the thermoelectric conversion part 120. The thermal energy may be discharged from the thermoelectric conversion part 120 to the low temperature region through the upper substrate 130. In detail, the heat sink 160 may transfer the thermal energy of the third electrode 123 to the upper substrate 130. However, the first and second electrodes 121 and 122 may hardly transfer the thermal energy to the upper substrate 130 due to the insulation member 150. The upper substrate 130 may discharge the thermal energy of the third electrode 123 to the low temperature region.

The lower substrate 110 may be disposed in the high temperature region. As described above, the first and second electrodes 121 and 122 may receive the thermal energy greater than that transferred to the third electrode 123 from the high temperature region. The first and second electrodes 121 and 122 may receive the thermal energy from the heat supply members 140.

Accordingly, according to embodiments of the inventive concept, the temperature difference between the first and third electrodes 121 and 123 may be greater than that of the thermoelectric device 100 in FIG. 2. The temperature difference between the second and third electrodes 122 and 123 may be greater than that of the thermoelectric device 100 in FIG. 2. Accordingly, according to embodiments of the inventive concept, the thermoelectric device 100a may generate the electrical energy greater than that of the thermoelectric device 100 in FIG. 2.

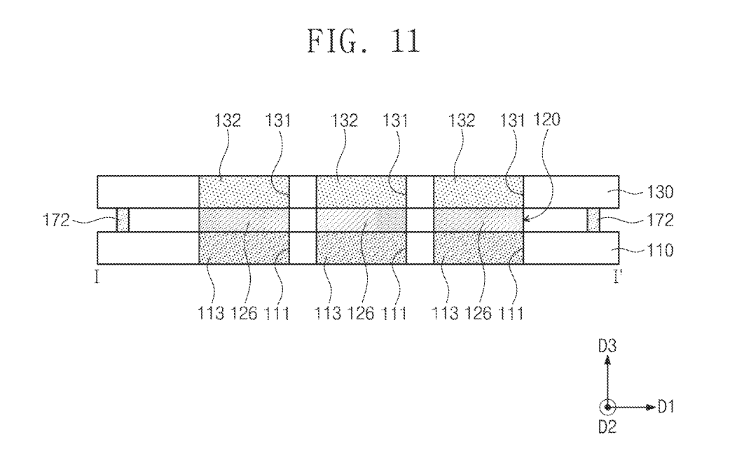

FIG. 10 is a view illustrating a thermoelectric generation apparatus according to embodiments of the inventive concept. FIG. 11 is a cross-sectional view taken along line I-I′ of FIG. 10. For simplicity in description, description for components that are substantially the same as those of embodiments described with reference to FIGS. 2 and 6 will be omitted or simply described.

Referring to FIGS. 10 to 11, a thermoelectric device 100b may include a lower substrate 110, a plurality of thermoelectric conversion parts 120, connecting electrodes 171 and 172, and an upper substrate 130. Each of the thermoelectric conversion parts 120 may include a first electrode 121, a second electrode 122, a third electrode 123, a first thermoelectric member 124 (refer to FIG. 3), and a second thermoelectric member 125 (refer to FIG. 3). According to embodiments of the inventive concept, the lower substrate 110 may have a first lower opening 111. Alternatively, according to another embodiment of the inventive concept, the lower substrate 110 may not have the first lower opening 111. The first lower opening 111 may be filled with a first heat transfer material 113 on the inside of the first lower opening 111. The first heat transfer material 113 may have the thermal conductivity less than that of the lower substrate 110.

The upper substrate 130 may have at least one upper opening 131 at a position corresponding to the third electrode 123. In detail, the upper opening 131 may extend from a top surface of the upper substrate 130 to the third electrode 123. According to embodiments of the inventive concept, the upper opening 131 may vertically extend from the top surface of the upper substrate 130 to the third electrode 123. Alternatively, according to another embodiment of the inventive concept, the upper opening 131 may extend to be inclined from the top surface of the upper substrate 130 to the third electrode 123. The upper opening 131 may expose an upper portion of the third electrode 123. For example, the upper opening 131 may be a hole.

The upper opening 131 may be filled with a second heat transfer material 132 on the inside of upper opening 131. The second heat transfer material 132 may have the thermal conductivity greater than that of the upper substrate 130. For example, although the second heat transfer material 132 may include gold (Au), silver (Ag), and copper (Cu), an embodiment of the inventive concept is not limited thereto. Accordingly, the third electrode 123 may transfer or receive the thermal energy more quickly than the first and second electrodes 121 and 122. The second heat transfer material 132 may be directly connected to the upper portion of the third electrode 123. Accordingly, the second heat transfer material 132 may receive or transfer the thermal energy from the third electrode 123.

According to embodiments of the inventive concept, the upper substrate 130 has twelve upper openings 131. The twelve upper openings 131 are arranged in the first direction D1 and the second direction D2. That is, the upper openings 131 may be arranged in a matrix structure.

According to embodiments of the inventive concept, the first and second electrodes 121 and 122 may receive the thermal energy in the high temperature region through the lower substrate 110. Also, the third electrode 123 may receive the thermal energy in the high temperature region through the first heat transfer material 113 in the first lower opening 111. However, since the first heat transfer material has the thermal conductivity less than that of the lower substrate 110, the third electrode 123 may receive the thermal energy in the high temperature region less than that of each of the first and second electrodes 121 and 122. Accordingly, the temperature difference may be generated between the first and third electrodes 121 and 123, and the temperature difference may be also generated between the second and third electrodes 123 and 123.

Also, the first and second electrodes 121 and 122 may receive the thermal energy from the heat supply members 140. Accordingly, the temperature difference between the first and third electrodes 121 and 123 may further increase. Also, the temperature difference between the second and third electrodes 122 and 123 may further increase.

The first and second electrodes 121 and 122 may transfer the thermal energy to the low temperature region through the upper substrate 130. Also, the third electrode 123 may transfer the thermal energy to the low temperature region through the second heat transfer material 132. Since the second heat transfer material 132 has the thermal conductivity greater than that of the upper substrate 130, the third electrode 123 may transfer the thermal energy greater than that of each of the first and second electrodes 121 and 122 to the low temperature region. Accordingly, the temperature difference between the first and third electrodes 121 and 123 may further increase. Also, the temperature difference between the second and third electrodes 122 and 123 may further increase.

According to embodiments of the inventive concept, the electrical energy generated by the thermoelectric device 100b may be greater than that generated by the thermoelectric device 100 in FIG. 2.

According to the embodiment of the inventive concept, the thermoelectric device may have the thermoelectric members in which the temperature difference at the both ends is great. Accordingly, the thermoelectric device may efficiently perform the thermoelectric generation.

The object of the present disclosure is not limited to the aforesaid, but other objects not described herein will be clearly understood by those skilled in the art from descriptions below.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A thermoelectric device comprising:
an upper substrate and a lower substrate, which face each other; and
a thermoelectric conversion part disposed between the upper substrate and the lower substrate,
wherein the thermoelectric conversion part comprises:
a first electrode disposed on the lower substrate;
a second electrode spaced apart from the first electrode in a first direction on the lower substrate;
a third electrode spaced apart from the first and second electrodes in a second direction perpendicular to the first direction on the lower substrate;
a first thermoelectric member disposed between the first electrode and the third electrode and connected to the first electrode and the third electrode; and
a second thermoelectric member disposed between the second electrode and the third electrode and connected to the second electrode and the third electrode,
wherein the lower substrate has a first lower opening that passes therethrough, and the first lower opening exposes the third electrode.

2. The thermoelectric device of claim 1, wherein the lower substrate comprises a first heat transfer material that fills the first lower opening, and the first heat transfer material has a thermal conductivity less than that of the lower substrate.

3. The thermoelectric device of claim 1, further comprising:
an insulation member disposed between the thermoelectric conversion part and the upper substrate; and
a heat sink disposed between the insulation member and the upper substrate,
wherein the insulation member has a through-hole that passes therethrough to expose the second electrode, and
the heat sink comprises a protruding portion inserted into the through-hole to contact the second electrode.

4. The thermoelectric device of claim 3, wherein the heat sink has a thermal conductivity greater than that of the insulation member.

5. The thermoelectric device of claim 1, wherein the lower substrate has a plurality of second lower openings disposed below the first and second electrodes, and
the thermoelectric device further comprises a plurality of heat supply members respectively disposed in the second lower openings to supply heat to the first and second electrodes.

6. The thermoelectric device of claim 5, wherein the heat supply members are spaced apart from the first and second electrodes.

7. The thermoelectric device of claim 1, wherein the upper substrate comprises:
an upper opening that passes therethrough to expose the third electrode; and
a second heat transfer material that fills the upper opening,
wherein the second heat transfer material has a thermal conductivity greater than that of the upper substrate.

8. The thermoelectric device of claim 1, wherein each of the upper and lower substrates comprises poly-dimethyllesiloxane (PDMS) or polyurethane.

9. The thermoelectric device of claim 1, wherein the first thermoelectric member comprises a first conductive semiconductor, and
the second thermoelectric member comprises a second conductive semiconductor that is different from the first conductive semiconductor.

10. The thermoelectric device of claim 9, wherein the first conductive semiconductor is one of a P-type semiconductor and a N-type semiconductor, and
the second conductive semiconductor is the other of the P-type semiconductor and the N-type semiconductor.

11. The thermoelectric device of claim 1, wherein the first direction and the second direction are parallel to a top surface of the lower substrate.

12. The thermoelectric device of claim 1, wherein each of the thermoelectric conversion part and the first lower opening is provided in plurality.

13. A thermoelectric device comprising:
an upper substrate and a lower substrate, which face each other;
a thermoelectric conversion part disposed between the upper substrate and the lower substrate;
an insulation member disposed between the thermoelectric conversion part and the upper substrate; and
a heat sink disposed between the insulation member and the upper substrate,
wherein the thermoelectric conversion part comprises:
a first electrode disposed on the lower substrate;
a second electrode spaced apart from the first electrode in a first direction on the lower substrate;
a third electrode spaced apart from the first and second electrodes in a second direction perpendicular to the first direction on the lower substrate;
a first thermoelectric member disposed between the first electrode and the third electrode to contact the first electrode and the third electrode; and
a second thermoelectric member disposed between the second electrode and the third electrode to contact the second electrode and the third electrode,
wherein the insulation member has a through-hole that passes therethrough to expose the third electrode, and
the heat sink comprises a protruding portion inserted into the through-hole to contact the third electrode.
